(19) United States
(12) Patent Application Publication
(10) Pub. No.: US 2026/0282786 A1
(43) Pub. Date: Sep. 17, 2026

(54) METHOD OF MANUFACTURING TREATED SUBSTRATE AND METHOD OF MANUFACTURING SEMICONDUCTOR

(71) Applicants: FUJIFILM Corporation, Tokyo (JP); FUJIFILM Electronic Materials U.S.A., Inc., North Kingstown, RI (US)

(72) Inventors: Koichi Sato, Shizuoka (JP); Atsushi Mizutani, Shizuoka (JP); Keeyoung Park, North Kingston, RI (US)

(73) Assignees: FUJIFILM Corporation, Tokyo (JP); FUJIFILM Electronic Materials U.S.A., Inc., North Kingstown, RI (US)

(21) Appl. No.: 19/675,743

(22) Filed: May 13, 2026

Related U.S. Application Data
(63) Continuation of application No. PCT/JP2024/038265, filed on Oct. 28, 2024.
(60) Provisional application No. 63/598,311, filed on Nov. 13, 2023.

(51) Int. Cl. H10P 50/68; C09D 183/16

(52) U.S. Cl. CPC H10P 50/68; C09D 183/16

(57) ABSTRACT

There are provided a method of manufacturing a treated substrate that can, in a substrate having on its surface at least two regions of a first region containing silicon and a second region made from a material different from that of the first region, suppress etching of the first region and achieve high etch selectivity between the two regions, and a method of manufacturing a semiconductor comprising the method of manufacturing a treated substrate. The method of manufacturing a treated substrate comprises a step 1 being a chemical solution treatment step, a step 2 being a cleaning step, and a step 3 being an etching step.

### CROSS-REFERENCE TO RELATED APPLICATIONS

This application is a Continuation of PCT International Application No. PCT/JP2024/038265 filed on Oct. 28, 2024, which claims priority under 35 U.S.C. § 119(e) to U.S. Patent Application No. 63/598,311 filed on Nov. 13, 2023. The above applications are hereby expressly incorporated by reference, in their entirety, into the present application.

### BACKGROUND OF THE INVENTION

The present invention relates to a method of manufacturing a treated substrate and a method of manufacturing a semiconductor.

With further miniaturization of semiconductor devices, formation of finer and more precise semiconductor devices has been desired. Conventionally, a photolithographic process has been used for formation of semiconductor devices. However, this process is becoming unsatisfactory in terms of currently required accuracy due to, for instance, errors in alignment of patterns.

To cope with it, a method that, using selective adsorption of a compound to a region formed from a specific material, selectively forms a film made from the compound, and treats a region other than the region formed from the specific material by utilizing the film, has been studied as a method of forming a semiconductor device.

Specifically, for example, there has been developed a method in which an etching step is carried out after a step of selectively forming, on a specific region, a coating inhibiting etching of a material such that a region without the coating is selectively etched.

For example, JP 2004-273519 A discloses “a method of forming a trench isolation structure, comprising: forming a groove on a surface of a silicon substrate; coating a polysilazane solution; prebaking the coating at a prebaking temperature regulated so that the temperature is raised in a temperature range of 50° C. to 400° C. over time; curing the coating at a temperature above the maximum prebaking temperature; and polishing and etching the resulting film.”

### SUMMARY OF INVENTION

The present inventors applied the selective etching method described in JP 2004-273519 A to a substrate having on its surface at least two regions of a first region containing silicon and a second region made from a material different from that of the first region, and thereby found that while etching of the first region is suppressed, etching of the second region is also suppressed, so that the etch selectivity between the two regions is low, and therefore further study is necessary.

An object of the present invention is to provide a method of manufacturing a treated substrate that can, in a substrate having on its surface at least two regions of a first region containing silicon and a second region made from a material different from that of the first region, suppress etching of the first region and achieve high etch selectivity between the two regions.

Another object of the present invention is to provide a method of manufacturing a semiconductor comprising the method of manufacturing a treated substrate.

The present inventors have made an intensive study to achieve the objects and as a result found that the foregoing objects can be achieved with the configuration below.
[1] A method of manufacturing a treated substrate, the method comprising:
a step 1 of bringing a substrate and a chemical solution into contact, the substrate having on its surface at least two regions of a first region containing silicon and a second region made from a material different from that of the first region, the chemical solution containing a silicon-containing organic compound and a solvent;
a step 2 of bringing the substrate having undergone the step 1 and an organic solvent into contact; and
a step 3 of bringing the substrate having undergone the step 2 and a treatment solution containing at least one of hydrogen fluoride, potassium hydroxide, ammonia, tetramethylammonium hydroxide, or hydrogen peroxide into contact, to thereby etch the second region.
[2] The method of manufacturing a treated substrate according to [1], wherein a step of heating the substrate is not carried out at least between the step 1 and the step 2 or between the step 2 and the step 3.
[3] The method of manufacturing a treated substrate according to [1] or [2], wherein the solvent in the chemical solution contains a non-protic polar solvent, and a content of the non-protic polar solvent is not less than 80 mass % with respect to a total mass of the solvent.
[4] The method of manufacturing a treated substrate according to any one of [1] to [3], wherein a content of water is less than 100 mass ppm with respect to a total mass of the chemical solution.
[5] The method of manufacturing a treated substrate according to any one of [1] to [4],
wherein the silicon-containing organic compound includes an organic compound having a Si—N bond.
[6] The method of manufacturing a treated substrate according to any one of [1] to [5],
wherein the silicon-containing organic compound is an organic silazane compound or a compound represented by Formula (1) to be described later.
[7] The method of manufacturing a treated substrate according to any one of [1] to [6],
wherein the silicon-containing organic compound is an organic silazane compound.
[8] The method of manufacturing a treated substrate according to any one of [1] to [7],
wherein a molecular weight of the silicon-containing organic compound is less than 200.
[9] The method of manufacturing a treated substrate according to any one of [1] to [8],
wherein the first region is a region containing at least one material selected from the group consisting of silicon, silicon oxide, silicon nitride, silicon carbide, silicon carbonitride, silicon oxycarbide, silicon oxycarbon nitride, and silicon germanium.
[10] The method of manufacturing a treated substrate according to any one of [1] to [9],
wherein the first region contains silicon oxide.
[11] A method of manufacturing a semiconductor, the method comprising the method of manufacturing a treated substrate according to any one of [1] to [10].

The present invention can provide a method of manufacturing a treated substrate that can, in a substrate having on its surface at least two regions of a first region containing silicon and a second region made from a material different from that of the first region, suppress etching of the first region and achieve high etch selectivity between the two regions.

The present invention can also provide a method of manufacturing a semiconductor comprising the method of manufacturing a treated substrate.

### DESCRIPTION OF THE PREFERRED EMBODIMENTS

The present invention is described in detail below.

While the constituent features are described based on typical embodiments of the invention in some cases, the present invention is not limited to those embodiments.

In the present specification, a numerical range expressed using “to” is a range including the numerical values stated before and after “to” as the lower and upper limits of the range.

In the present specification, the term “ppm” represents “parts-per-million (10⁻⁶),” the term “ppb” represents “parts-per-billion (10⁻⁹),” and the term “ppt” represents “parts-per-trillion (10⁻¹²).”

In the present specification, when two or more kinds of a certain component are present, the “content” of the component means a total content of the two or more kinds.

Compounds described in the present specification may include structural isomers, optical isomers, and isotopes unless noted otherwise. For structural isomers, optical isomers, and isotopes, only one kind or two or more kinds may be included.

In the present specification, in terms of a binding direction of a divalent group (e.g., —COO—), when Y in a compound expressed by “X—Y—Z” is —COO—, the compound may be “X—O—CO—Z” or “X—CO—O—Z” unless noted otherwise.

In the present specification, when there are plural substituents and plural linking groups (hereinafter referred to as substituents and the like) represented by a specific symbol or when plural substituents and the like are simultaneously defined, the substituents and the like may be the same as or different from each other. The same applies to the definition of the number of substituents and the like.

### {Method of Manufacturing a Treated Substrate}

The method of manufacturing a treated substrate according to the present invention is described below in detail.

The method of manufacturing a treated substrate according to the present invention is a method comprising steps 1 to 3 which will be described later.

While the reason why the method of manufacturing a treated substrate with the above configuration can achieve the objects of the present invention is not necessarily clear, the present inventors assume as described below.

It should be noted that the assumption described below does not limit the mechanism as to how effects are obtained. In other words, cases where other mechanisms than the one described below work to obtain effects are also within the scope of the present invention.

In the method of manufacturing a treated substrate according to the present invention, a highly hydrophobic, silicon atom-containing coating that is derived from a silicon-containing organic compound is formed on a first region through the step 1. After this step, the step 2 is carried out to bring a substrate and an organic solvent into contact, whereby the silicon-containing organic compound unintentionally remaining on a second region can be removed, and this is assumed to be one possible reason why the etch selectivity between the first region and the second region is high.

The method of manufacturing a treated substrate according to the present invention is hereinafter referred to also simply as the “method of manufacturing a treated substrate.” Etching of the first region being suppressed and having higher etch selectivity between the regions in the substrate are referred to also as “the effects of the present invention are more excellent.”

### (Step 1)

The method of manufacturing a treated substrate according to the present invention comprises steps 1 to 3 which will be described in detail later. The step 1 is described in detail below.

The step 1 is a step of bringing a substrate and a chemical solution into contact, the substrate having on its surface at least two regions of a first region containing silicon and a second region made from a material different from that of the first region (hereinafter also referred to as the “specific substrate”), the chemical solution containing a silicon-containing organic compound and a solvent (hereinafter also simply referred to as the “chemical solution”).

The chemical solution and the specific substrate are detailed first, and then specific procedures for bringing the specific substrate and the chemical solution into contact in the step 1 are described.

### <<Chemical Solution>>

The chemical solution contains a silicon-containing organic compound and a solvent.

### <Silicon-Containing Organic Compound>

The silicon-containing organic compound is an organic compound containing a silicon atom. The type of the silicon-containing organic compound is not particularly limited, and the silicon-containing organic compound is a compound containing at least a silicon atom and a carbon atom.

For the silicon-containing organic compound, a silylating agent is preferred. A silylating agent is a compound capable of introducing a silyl group by reacting with a functional group present on a surface of the specific substrate. Examples of the functional group include a hydroxyl group, an amino group, a carboxy group, and an amido group.

Examples of the silylating agent include an organic compound having a Si—N bond to be described later, an alkoxysilane compound to be described later, and a chlorosilane compound to be described later.

For the silicon-containing organic compound, an organic compound having a Si—N bond or an alkoxysilane compound is preferred, an organic compound having a Si—N bond is more preferred, an organic silazane compound (an organic compound having a Si—N—Si structure) or a compound represented by Formula (1) to be described later is even more preferred, and an organic silazane compound is particularly preferred.

The organic silazane compound is an organic compound having a silazane structure (Si—N—Si structure), and a preferred silazane structure is a Si—NH—Si structure.

As described above, the silicon-containing organic compound preferably includes an organic compound having a Si—N bond. The number of Si—N bonds included in the organic compound having a Si—N bond is not particularly limited and is preferably 1 to 4, more preferably 2 to 3, and even more preferably 2.

The number of carbon atoms included in the organic compound having a Si—N bond is not particularly limited and is preferably 1 to 25, more preferably 2 to 15, and even more preferably 3 to 12.

### —Organic Silazane Compound

The organic silazane compound is an organic compound having a Si—N—Si bond. The number of Si—N—Si bonds is not particularly limited and is preferably 1 to 3, and more preferably 1.

For the organic silazane compound, an organic disilazane compound is preferred, and a compound represented by Formula (2) is more preferred.

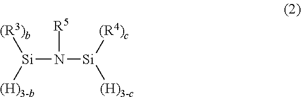

R³ and R⁴ each independently represent a hydrocarbon group that may have a halogen atom.

The definition and preferred embodiments of the hydrocarbon group represented by R³ and R⁴ are the same as those for a hydrocarbon group represented by R¹ in Formula (1) which will be described later.

When a plurality of R³'s are present, plural groups each represented by R³ may be the same or different. When a plurality of R⁴'s are present, plural groups each represented by R⁴ may be the same or different.

R⁵ represents a hydrogen atom or a hydrocarbon group that may have a halogen atom.

The definition and preferred embodiments of the hydrocarbon group represented by R⁵ are the same as those for a hydrocarbon group represented by R² in Formula (1) which will be described later.

R⁵ is preferably a hydrogen atom.

b and c each independently represent an integer of 1 to 3, preferably 2 or 3, and more preferably 2.

Examples of the organic silazane compound include hexamethyldisilazane (HMDS), tetramethyldisilazane (TMDS), tetraethyldisilazane, hexaethyldisilazane, tetrapropyldisilazane, hexapropyldisilazane, tetrabutyldisilazane, and hexabutyldisilazane, with TMDS or HMDS being preferred.

Other than the foregoing examples, examples of the organic silazane compound further include [C₄H₉(CH₃)₂Si]₂NH, [C₅H₁₁(CH₃)₂Si]₂NH, [CH₁₃(CH₃)₂Si]₂NH, [C₇H₁₅(CH₃)₂Si]₂NH, [C₈H₁₇(CH₃)₂Si]₂NH, [C₉H₁₉(CH₃)₂Si]₂NH, [C₁₀H₂₁(CH₃)₂Si]₂NH, [C₁₁H₂₃(CH₃)₂Si]₂NH, [C₁₂H₂₅(CH₃)₂Si]₂NH, [C₁₃H₂₇(CH₃)₂Si]₂NH, [C₁₄H₂₉(CH₃)₂Si]₂NH, [C₁₅H₃₁(CH₃)₂Si]₂NH, [C₁₆H₃₃(CH₃)₂Si]₂NH, [C₁₇H₃₅(CH₃)₂Si]₂NH, [C₁₈H₃₇(CH₃)₂Si]₂NH, [C₂ F₁₇C₂H₄(CH₃)₂Si]₂NH, [C₃F₇C₂H₄(CH₃)₂Si]₂NH, [C₄F₉C₂H₄(CH₃)₂Si]₂NH, [C₅F₁₁C₂H₄(CH₃)₂Si]₂NH, [C₆F₁₃C₂H₄(CH₃)₂Si]₂NH, [C₇F₁₅C₂H₄(CH₃)₂Si]₂NH, [C₈F₁₇C₂H₄(CH₃)₂Si]₂NH, [(C₂H₅)₃Si]₂NH, [C₃H₇(C₂H₅)₂Si]₂NH, [C₄H₉(C₂H₅)₂Si]₂NH, [C₅H₁₁(C₂H₅)₂Si]₂NH, [CH₁₃(C₂H₅)₂Si]₂NH, [C₇H₁₅(C₂H₅)₂Si]₂NH, [C₈H₁₇(C₂H₅)₂Si]₂NH, [C₉H₁₉(C₂H₅)₂Si]₂NH, [C₁₀H₂₁(C₂H₅)₂Si]₂NH, [C₁₁H₂₃(C₂H₅)₂Si]₂NH, [C₁₂H₂₅(C₂H₅)₂Si]₂NH, [C₁₃H₂₇(C₂H₅)₂Si]₂NH, [C₁₄H₂₉(C₂H₅)₂Si]₂NH, [C₁₅H₃₁(C₂H₅)₂Si]₂NH, [C₁₆H₃₃(C₂H₅)₂Si]₂NH, [C₁₇H₃ (C₂H₅)₂Si]₂NH, and [C₁₈H₃₇(C₂H₅)₂Si]₂NH.

### Compound Represented by Formula (1)

Next, the compound represented by Formula (1) is described.

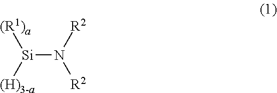

In Formula (1), R¹'s each independently represent a hydrocarbon group (monovalent hydrocarbon group) that may have a halogen atom.

The number of carbon atoms of the hydrocarbon group is preferably 1 to 25.

Examples of the hydrocarbon group include an alkyl group, an alkenyl group, and an aryl group.

The alkyl group may be linear, branched, or cyclic and is preferably linear.

The number of carbon atoms of a linear or branched alkyl group is preferably 1 to 18, more preferably 1 to 6, even more preferably 1 to 4, and particularly preferably 1 or 2. Examples of the linear or branched alkyl group include a methyl group, an ethyl group, an n-propyl group, an isopropyl group, a butyl group, a sec-butyl group, a t-butyl group, an n-hexyl group, an n-heptyl group, an n-octyl group, an n-nonyl group, and an n-decyl group, with a methyl group, an ethyl group, an n-propyl group, an n-butyl group, or a t-butyl group being preferred, and a methyl group or an ethyl group being more preferred.

The number of carbon atoms of a cyclic alkyl group (cycloalkyl group) is preferably 3 to 18, more preferably 3 to 12, and even more preferably 3 to 6. Examples of the cycloalkyl group include a cyclopropyl group and a cyclohexyl group.

The number of carbon atoms of the alkenyl group is preferably 2 to 12, more preferably 2 to 6, and even more preferably 2 to 4. Examples of the alkenyl group include a vinyl group or an allyl group.

The number of carbon atoms of the aryl group is preferably 5 to 8 and more preferably 5 or 6. One example of the aryl group is a phenyl group.

Examples of a halogen atom that the monovalent hydrocarbon group may have include a fluorine atom, a chlorine atom, a bromine atom, and an iodine atom, with a fluorine atom being preferred. When the monovalent hydrocarbon group has a halogen atom, the alkyl group may be a perfluoroalkyl group, for example.

For the group represented by R¹, an alkyl group with 1 to 25 carbon atoms that may have a halogen atom is preferred, a linear alkyl group with 1 to 18 carbon atoms that may have a halogen atom is more preferred, and a linear alkyl group with 1 to 6 carbon atoms that may have a halogen atom is even more preferred.

When a plurality of R¹'s are present, plural groups each represented by R¹ may be the same or different.

R²'s each independently represent a hydrogen atom, a hydrocarbon group that may have a halogen atom, or an acyl group that may have a halogen atom (R—CO—; R representing a hydrocarbon group that may have a halogen atom).

The number of carbon atoms of the hydrocarbon group is preferably 1 to 18.

Examples of the hydrocarbon group include an alkyl group that may have an aryl group, and an aryl group.

The alkyl group may be linear, branched, or cyclic. The number of carbon atoms of a linear or branched alkyl group is preferably 1 to 6, more preferably 1 to 4, and even more preferably 1 or 2. Examples of the linear or branched alkyl group include a methyl group, an ethyl group, an n-propyl group, an isopropyl group, a butyl group, a sec-butyl group, a t-butyl group, an n-hexyl group, an n-heptyl group, an n-octyl group, an n-nonyl group, and an n-decyl group, with a methyl group, an ethyl group, an n-propyl group, or an n-butyl group being preferred, and a methyl group or an ethyl group being more preferred.

The number of carbon atoms of a cyclic alkyl group (cycloalkyl group) is preferably 3 to 12, and more preferably 3 to 6. Examples of the cycloalkyl group include a cyclopropyl group and a cyclohexyl group.

The number of carbon atoms of the aryl group (including an aryl group that the alkyl group may have) is preferably 5 to 8 and more preferably 5 or 6. One example of the aryl group is a phenyl group.

Examples of a halogen atom that the hydrocarbon group may have include a fluorine atom, a chlorine atom, a bromine atom, and an iodine atom, with a fluorine atom being preferred. When the monovalent hydrocarbon group has a halogen atom, the alkyl group may be a perfluoroalkyl group.

The definition and preferred embodiments of the hydrocarbon group that may have a halogen atom contained in the acyl group are the same as those for the hydrocarbon group that may have a halogen atom as represented by R².

For the group represented by R², a hydrogen atom, an alkyl group with 1 to 4 carbon atoms that may have a halogen atom, or an acyl group with 2 to 4 carbon atoms that may have a halogen atom is preferred, a hydrogen atom or an alkyl group with 1 to 4 carbon atoms is more preferred, and a hydrogen atom or a methyl group is even more preferred.

Plural groups each represented by R² may be the same or different.

a represents an integer of 1 to 3, preferably 2 or 3, and more preferably 3.

Examples of the compound represented by Formula (1) include: alkyldimethyl(dimethylamino)silanes such as C₃H₇(CH₃)₂SiN(CH₃)₂, C₄H₉(CH₃)₂SiN(CH₃)₂, C₅H₁₁(CH₃)₂SiN(CH₃)₂, C₆H₁₃(CH₃)₂SiN (CH₃)₂, C₇H₁₅(CH₃)₂SiN (CH₃)₂, C₈H₁₇(CH₃)₂SiN (CH₃)₂, C₉H₁₉(CH₃)₂SiN (CH₃)₂, C₁₀H₂₁(CH₃)₂SiN (CH₃)₂, C₁₁H₂₃(CH₃)₂SiN (CH₃)₂, C₁₂H₂₅(CH₃)₂SiN (CH₃)₂, C₁₃H₂₇(CH₃)₂SiN (CH₃)₂, C₁₄H₂₉(CH₃)₂SiN (CH₃)₂, C₁₅H₃₁(CH₃)₂SiN (CH₃)₂, C₁₆H₃₃(CH₃)₂SiN (CH₃)₂, C₁₇H₃₅(CH₃)₂SiN (CH₃)₂, C₁₈H₃₇(CH₃)₂SiN (CH₃)₂, and C₃₀H₆i (CH₃)₂SiN (CH₃)₂; alkylmethyl (dimethylamino) silanes such as C₅H₁₁(CH₃)HSiN(CH₃)₂, C₆H₁₃(CH₃)HSiN(CH₃)₂, C₇H₁₅(CH₃)HSiN(CH₃)₂, C₈H₁₇(CH₃)HSiN(CH₃)₂, C₉H₁₉(CH₃)HSiN(CH₃)₂, C₁₀H₂₁(CH₃)HSiN(CH₃)₂, C₁₁H₂₃(CH₃)HSiN(CH₃)₂, C₁₂H₂₅(CH₃)HSiN(CH₃)₂, C₁₃H₂₇(CH₃)HSiN(CH₃)₂, C₁₄H₂₉(CH₃)HSiN(CH₃)₂, C₁₅H₃₁(CH₃)HSiN(CH₃)₂, C₁₆H₃₃(CH₃)HSiN(CH₃)₂, C₁₇H₃₅(CH₃)HSiN(CH₃)₂, C₁₈H₃₇(CH₃)HSiN(CH₃)₂, and C₃₀H₆i (CH₃)HSiN(CH₃)₂; fluoroalkylethyl(dimethylamino)silanes such as C₂F₅C₂H₄(CH₃)₂SiN(CH₃)₂, C₃F₇C₂H₄(CH₃)₂SiN(CH₃)₂, C₄F₉C₂H₄(CH₃)₂SiN(CH₃)₂, C₅F₁₁C₂H₄(CH₃)₂SiN(CH₃)₂, C₆F₁₃C₂H₄(CH₃)₂SiN (CH₃)₂, C₇F₁₅C₂H₄(CH₃)₂SiN (CH₃)₂, and C₈F₁₇C₂H₄(CH₃)₂SiN (CH₃)₂; aryl-alkylmethyl (dimethylamino) silanes such as phenethyldimethyl(dimethylamino)silane; N-(alkyldimethylsilyl)-N-methylacetamides such as (CH₃)₃SiN(CH₃)COCH₃ and C₄H (CH₃)₂SiN(CH₃)COCH₃; N-(alkyldimethylsilyl)-N-methylfluoroacetamides such as (CH₃)₃SiN(CH₃)COCF₃ (N-methyl-N-trimethylsilyl trifluoroacetamide: MSTFA) and C₄H₉(CH₃)₂SiN (CH₃) COCF₃ (N-methyl-N-(tert-butyldimethylsilyl)-trifluoroacetamide: MTBSTFA); alkyldimethyl(dimethylamino)silane, alkylmethyl(dimethylamino)silane, fluoroalkylethyl(dimethylamino)silane, N-(alkyldimethylsilyl)-N-methylfluoroacetamide, and a compound in which a methyl group in N-(alkyldimethylsilyl)-N-methylfluoroacetamide is substituted with an alkyl group with 1 to 18 carbon atoms such as an ethyl group, a propyl group, or a butyl group.

Of these, for the compound represented by Formula (1), C₃H₇(CH₃)₂SiN(CH₃)₂, C₄H₉(CH₃)₂SiN(CH₃)₂, C₅H₁₁(CH₃)₂SiN(CH₃)₂, C₆H₁₃(CH₃)₂SiN (CH₃)₂, C₇H₁₅(CH₃)₂SiN (CH₃)₂, C₈H₁₇(CH₃)₂SiN (CH₃)₂, MSTFA, or MTBSTFA is preferred, and C₄H₉(CH₃)₂SiN(CH₃)₂ is more preferred.

Other than the foregoing examples, exemplary compounds having a Si—N bond further include N,O-bis(trimethylsilyl) trifluoroacetamide (BSTFA) and N-trimethylsilylimidazole (TMSI).

### Compound Represented by Formula (3)

For the silicon-containing organic compound, a compound represented by Formula (3) is also favorable.

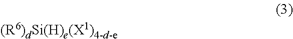

In Formula (3), R⁶'s each independently represent a hydrocarbon group that may have a halogen atom.

The definition and preferred embodiments of the hydrocarbon group represented by R⁶ are the same as those for the hydrocarbon group represented by R¹ in Formula (1).

For the group represented by R⁶, an alkyl group with 1 to 25 carbon atoms that may have a halogen atom is preferred, and a linear alkyl group with 1 to 20 carbon atoms is more preferred.

When a plurality of R⁶'s are present, plural groups each represented by R⁶ may be the same or different.

When a plurality of R⁶'s are present, the sum of carbon atoms of all the groups each represented by R⁶ is preferably 3 to 35 and more preferably 3 to 25.

X¹ represents a hydrolyzable group. Examples of the hydrolyzable group include a —O—R⁷ group and a halogen atom. R⁷ represents a hydrocarbon group that may have a halogen atom.

The definition and preferred embodiments of the hydrocarbon group represented by R⁷ are the same as those for the hydrocarbon group represented by R² in Formula (1).

Examples of the halogen atom include a chlorine atom, a bromine atom, and an iodine atom, with a chlorine atom being preferred.

For X¹, a —O—R⁷ group is preferred, an alkoxy group is more preferred, and an alkoxy group with 1 to 3 carbon atoms is even more preferred.

When a plurality of X¹'s are present, plural groups each represented by X¹ may be the same or different, and are preferably the same.

d represents an integer of 1 to 3, preferably 1 or 2, and more preferably 1.

e represents an integer of 0 to 2 and preferably 0.

d+e represents an integer of 1 to 3, preferably 1 or 2, and more preferably 1.

Examples of the silicon-containing organic compound represented by Formula (3) include an alkoxysilane compound (a compound represented by Formula (3), where X¹ is an alkoxy group) and a chlorosilane compound (a compound represented by Formula (3), where X¹ is a chlorine atom).

Examples of the alkoxysilane compound include alkyl methoxy silanes such as CH₃Si(OCH₃)₃, C₂H₅Si(OCH₃)₃, C₃H₇Si(OCH₃)₃, C₄H₉Si(OCH₃)₃, C₅H₁₁Si(OCH₃)₃, C₆H₁₃Si(OCH₃)₃, C₇H₁₅Si(OCH₃)₃, C₈H₁₇Si(OCH₃)₃, C₉H₁₉Si(OCH₃)₃, C₁₀H₂₁Si(OCH₃)₃, C₁₁H₂₃Si(OCH₃)₃, C₁₂H₂₅Si(OCH₃)₃, C₁₃H₂₇Si(OCH₃)₃, C₁₄H₂₉Si(OCH₃)₃, C₁₅H₃₁Si(OCH₃)₃, C₁₆H₃₃Si(OCH₃)₃, C₁₇H₃₅Si(OCH₃)₃, C₁₈H₃₇Si(OCH₃)₃, C₂₀H₄₁Si(OCH₃)₃, C₂₄H₄₉Si(OCH₃)₃, (CH₃)₂Si(OCH₃)₂, C₂H₅Si(CH₃)(OCH₃)₂, (C₂H₅)₂Si(OCH₃)₂, C₃H₇Si(CH₃)(OCH₃)₂, (C₃H₇)₂Si(OCH₃)₂, C₄H₉Si(CH₃)(OCH₃)₂, (C₄H₉)₂Si(OCH₃)₂, C₅H₁₁Si(CH₃)(OCH₃)₂, C₆H₁₃Si(CH₃)(OCH₃)₂, C₇H₁₅Si(CH₃)(OCH₃)₂, C₈H₁₇Si(CH₃)(OCH₃)₂, C₉H₁₁Si(CH₃)(OCH₃)₂, C₁₀H₂₁Si(CH₃)(OCH₃)₂, C₁₁H₂₃Si(CH₃)(OCH₃)₂, C₁₂H₂₅Si(CH₃)(OCH₃)₂, C₁₃H₂₇Si(CH₃)(OCH₃)₂, C₁₄H₂₉Si(CH₃)(OCH₃)₂, C₁₅H₃₁Si(CH₃)(OCH₃)₂, C₁₆H₃₃Si(CH₃)(OCH₃)₂, C₁₇H₃₅Si(CH₃)(OCH₃)₂, C₁₈H₃₇Si(CH₃)(OCH₃)₂, (CH₃)₃SiOCH₃, C₂H₅Si(CH₃)₂OCH₃, (C₂H₅)₂Si(CH₃) OCH₃, (C₂H₅)₃SiOCH₃, C₃H₇Si(CH₃)₂OCH₃, (C₃H₇)₂Si(CH₃)OCH₃, (C₃H₇)₃SiOCH₃, C₄H₉Si(CH₃)₂OCH₃, (C₄H₉)₃SiOCH₃, C₅H₁₁Si(CH₃)₂OCH₃, C₆H₁₃Si(CH₃)₂OCH₃, C₇H₁₅Si(CH₃)₂OCH₃, C₈Hi Si(CH₃)₂OCH₃, C₉H₁₉Si(CH₃)₂OCH₃, C₁₀H₂₁Si(CH₃)₂OCH₃, C₁₁H₂₃Si(CH₃)₂OCH₃, C₁₂H₂₅Si(CH₃)₂OCH₃, C₁₃H₂₇Si(CH₃)₂OCH₃, C₁₄H₂₉Si(CH₃)₂OCH₃, C₁₅H₃₁Si(CH₃)₂OCH₃, C₁₆H₃₃Si(CH₃)₂OCH₃, C₁₇H₃₅Si(CH₃)₂OCH₃, C₁₈H₃₇Si(CH₃)₂OCH₃, (CH₃)₂Si(H) OCH₃, CH₃Si(H)₂OCH₃, (C₂H₅)₂Si(H) OCH₃, C₂H₅Si(H)₂OCH₃, C₂H₅Si(CH₃)(H) OCH₃, and (C₃H₇)₂Si(H) OCH₃; fluoromethoxy silanes such as CF₃CH₂CH₂Si(OCH₃)₃, C₂F₅CH₂CH₂Si(OCH₃)₃, C₃F₇CH₂CH₂Si(OCH₃)₃, C₄F₉CH₂CH₂Si(OCH₃)₃, C₅F₁₁CH₂CH₂Si(OCH₃)₃, C₆F₁₃CH₂CH₂Si(OCH₃)₃, C₇F₁₅CH₂CH₂Si(OCH₃)₃, C₈F₁₇CH₂CH₂Si(OCH₃)₃, CF₃CH₂CH₂Si(CH₃)(OCH₃)₂, C₂F₅CH₂CH₂Si(CH₃)(OCH₃)₂, C₃F₇CH₂CH₂Si(CH₃)(OCH₃)₂, C₄F₉CH₂CH₂Si(CH₃)(OCH₃)₂, C₅F₁₁CH₂CH₂Si(CH₃)(OCH₃)₂, C₆F₁₃CH₂CH₂Si(CH₃)(OCH₃)₂, C₇F₁₅CH₂CH₂Si(CH₃)(OCH₃)₂, C₈F₁₇CH₂CH₂Si(CH₃)(OCH₃)₂, CF₃CH₂CH₂Si(CH₃)₂OCH₃, C₂F₅CH₂CH₂Si(CH₃)₂OCH₃, C₃F₇CH₂CH₂Si(CH₃)₂OCH₃, C₄F₉CH₂CH₂Si(CH₃)₂OCH₃, C₅F₁₁CH₂CH₂Si(CH₃)₂OCH₃, C₆F₁₃CH₂CH₂Si(CH₃)₂OCH₃, C₇F₁₅CH₂CH₂Si(CH₃)₂OCH₃, C₈F₁₇CH₂CH₂Si(CH₃)₂OCH₃, and CF₃CH₂CH₂Si(CH₃)(H) OCH₃; and an alkoxy silane compound in which a methoxy group in an alkyl methoxy silane and a fluoromethoxy silane is substituted with an alkoxy group with 2 to 10 carbon atoms.

Examples of the chlorosilane compound include trimethylchlorosilane (TMCS), triethylchlorosilane, tributylchlorosilane, triphenylchlorosilane, dimethyldichlorosilane (DMCS), t-butyldimethylchlorosilane, dimethylphenylchlorosilane, and di-tert-butyldichlorosilane.

For the silane compound represented by Formula (3), an alkoxysilane compound is preferred, an alkyl methoxy silane is more preferred, and an alkyl trimethoxy silane is even more preferred.

The molecular weight of the silicon-containing organic compound is preferably not more than 500, more preferably not more than 300, and even more preferably less than 200. The lower limit thereof is not particularly limited and is usually not less than 50.

The silicon-containing organic compounds may be used singly or in combination of two or more thereof.

The content of the silicon-containing organic compound is preferably 0.01 to 10 mass %, more preferably 0.1 to 5 mass %, and even more preferably 0.3 to 3 mass % with respect to the total mass of the chemical solution.

### <Solvent>

The solvent contained in the chemical solution is not particularly limited as long as it is a solvent capable of dissolving the silicon-containing organic compound, and preferably contains a non-protic solvent and more preferably contains a non-protic polar solvent.

When the solvent in the chemical solution contains a non-protic solvent (more preferably, a non-protic polar solvent), the content of the non-protic solvent (more preferably, the non-protic polar solvent) is preferably not less than 50 mass %, more preferably not less than 60 mass %, even more preferably not less than 80 mass %, and particularly preferably 100 mass % with respect to the total mass of the solvent contained in the chemical solution.

### Non-Protic Solvent

The non-protic solvent is a solvent that does not have a proton donating ability.

Examples of the non-protic solvent include a carbonate solvent, an ester solvent, an ether solvent, a ketone solvent, a hydrocarbon solvent, a halogen-containing solvent, a sulfoxide solvent, and a nitrogen-containing solvent free of a N—H bond.

Examples of the carbonate solvent include propylene carbonate, dimethyl carbonate, diethyl carbonate, and ethyl methyl carbonate.

Examples of the ester solvent include: chain ester solvents such as ethyl acetate, propyl acetate, butyl acetate, methoxybutyl acetate, ethylene glycol monomethyl ether acetate, ethylene glycol monoethyl ether acetate, ethylene glycol monobutyl ether acetate, ethylene glycol diacetate, diethylene glycol monomethyl ether acetate, diethylene glycol monoethyl ether acetate, diethylene glycol monobutyl ether acetate, diethylene glycol diacetate, triethylene glycol monomethyl ether acetate, triethylene glycol monoethyl ether acetate, triethylene glycol monobutyl ether acetate, triethylene glycol diacetate, tetraethylene glycol monomethyl ether acetate, tetraethylene glycol monoethyl ether acetate, tetraethylene glycol monobutyl ether acetate, tetraethylene glycol diacetate, propylene glycol monomethyl ether acetate, propylene glycol monoethyl ether acetate, propylene glycol monobutyl ether acetate, propylene glycol diacetate, dipropylene glycol monomethyl ether acetate, dipropylene glycol monoethyl ether acetate, dipropylene glycol monobutyl ether acetate, dipropylene glycol diacetate, tripropylene glycol monomethyl ether acetate, tripropylene glycol monoethyl ether acetate, tripropylene glycol monobutyl ether acetate, tripropylene glycol diacetate, tetrapropylene glycol monomethyl ether acetate, tetrapropylene glycol diacetate, and butylene glycol monomethyl ether acetate; and lactone solvents such as γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, and c-hexanolactone.

Examples of the ether solvent include: glycol dialkyl ether solvents such as ethylene glycol dimethyl ether, ethylene glycol diethyl ether, ethylene glycol dibutyl ether, diethylene glycol dimethyl ether, diethylene glycol ethyl methyl ether, diethylene glycol diethyl ether, diethylene glycol butyl methyl ether, diethylene glycol dibutyl ether, triethylene glycol dimethyl ether, triethylene glycol diethyl ether, triethylene glycol dibutyl ether, triethylene glycol butyl methyl ether, tetraethylene glycol dimethyl ether, tetraethylene glycol diethyl ether, tetraethylene glycol dibutyl ether, propylene glycol dimethyl ether, propylene glycol diethyl ether, propylene glycol dibutyl ether, dipropylene glycol dimethyl ether, dipropylene glycol methyl propyl ether, dipropylene glycol diethyl ether, dipropylene glycol dibutyl ether, tripropylene glycol dimethyl ether, tripropylene glycol diethyl ether, tripropylene glycol dibutyl ether, tetrapropylene glycol dimethyl ether, and butylene glycol dimethyl ether; dialkyl ether solvents such as diethyl ether, dipropyl ether, ethyl butyl ether, dibutyl ether, ethyl amyl ether, diamyl ether, methyl cyclopentyl ether, ethylhexyl ether, dihexyl ether, and dioctyl ether; and cyclic ether solvents such as tetrahydrofuran and dioxane.

Examples of the ketone solvents include acetone, acetylacetone, methyl ethyl ketone, methyl propyl ketone, methyl butyl ketone, cyclohexanone, and isophorone.

Examples of the hydrocarbon solvent include: aromatic hydrocarbon solvents such as benzene, toluene, xylene, ethylbenzene, and tetralin; and aliphatic hydrocarbon solvents such as hexane, heptane, octane, and cyclohexane.

Examples of the halogen-containing solvent include: perfluorocarbons such as perfluorooctane, perfluorononane, perfluorocyclopentan, perfluorocyclohexane, and hexafluorobenzene; hydrofluorocarbons such as 1,1,1,3,3-pentafluorobutane, octafluorocyclopentane, 2,3-dihydrodecafluoropentane, and ZEORORA H (manufactured by Zeon Corporation); hydrofluoroethers such as methyl perfluoroisobutyl ether, methyl perfluorobutyl ether, ethyl perfluorobutyl ether, ethyl perfluoroisobutyl ether, ASAHIKLIN AE-3000 (manufactured by AGC Inc.), and Novec 7100, Novec 7200, Novec 7300, and Novec 7600 (manufactured by 3M); chlorocarbons such as tetrachloromethane; hydrochlorocarbons such as chloroform; chlorofluorocarbons such as dichlorodifluoromethane; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, and 1,2-dichloro-3,3,3-trifluoropropene; perfluoroether; and perfluoropolyether.

Examples of the sulfoxide solvent include dimethyl sulfoxide.

Examples of the nitrogen-containing solvent free of a N—H bond include N,N-dimethylformamide, N,N-dimethylacetamide, N-methyl-2-pyrrolidone, triethylamine, and pyridine.

For the non-protic solvent, the carbonate solvent, the ester solvent, or the ether solvent is preferred, the carbonate solvent, a cyclic ester solvent, or a glycol ether solvent is more preferred, and the carbonate solvent is even more preferred.

In particular, propylene carbonate, γ-butyrolactone, γ-valerolactone, PGMEA, ethylene glycol dibutyl ether, diethylene glycol diethyl ether, diethylene glycol dibutyl ether, propylene glycol dimethyl ether, or propylene glycol dibutyl ether is preferred, propylene carbonate, γ-butyrolactone, γ-valerolactone, propylene glycol dimethyl ether, or diethylene glycol dibutyl ether is more preferred, and propylene carbonate is even more preferred.

### Alcohol

The solvent may contain a solvent other than the non-protic solvent. One example of the solvent other than the non-protic solvent is an alcohol.

The alcohol is an organic compound having at least one alcoholic hydroxyl group.

It suffices if the number of hydroxyl groups that the alcohol has is 1 or more, and 2 or more is preferred. The upper limit thereof is not particularly limited and is preferably 6 or less, and more preferably 4 or less.

The alcohol may be linear or branched and is preferably linear. The alcohol may have a cyclic structure in the molecule.

The number of carbon atoms included in the alcohol is not particularly limited and is preferably 1 to 25, more preferably 1 to 15, even more preferably 2 to 10, and particularly preferably 2 to 6.

The molecular weight of the alcohol is not particularly limited and is preferably not more than 300, more preferably not more than 200, and even more preferably not more than 150. The lower limit thereof is not particularly limited and is preferably not less than 30, and more preferably not less than 40.

The alcohol may have an etheric oxygen atom in the molecule. The etheric oxygen atom refers to an oxygen atom present in a carbon-carbon bond in the molecule. Examples of the alcohol having an etheric oxygen atom in the molecule include dialkylene glycol, trialkylene glycol, polyalkylene glycol, alkylene glycol monoalkyl ether, dialkylene glycol monoalkyl ether, trialkylene glycol monoalkyl ether, and polyalkylene glycol monoalkyl ether.

Examples of the alcohol include: monools such as 1-propanol, 1-butanol, 1-pentanol, 1-hexanol, 1-heptanol, 1-octanol, lauryl alcohol, 1-decanol, 1-nonanol, 1-octadecanol, methanol, ethanol, 2-ethylhexanol, isopropanol (2-propanol), 2-butanol, isobutyl alcohol, 3-methyl-1-butanol, tert-butyl alcohol, 2-pentanol, t-pentyl alcohol, 4-methyl-2-pentanol, 2-hexanol, cyclopentanol, 2-heptanol, 2-octanol, 2-ethylpentanol, 4-octanol, 3-methoxy-3-methyl-1-butanol, 3-methoxy-1-butanol, and 1-methoxy-2-butanol; glycols such as propylene glycol, ethylene glycol, diethylene glycol, dipropylene glycol, triethylene glycol, tetraethylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, hexylene glycol, pinacol, and 1,3-cyclopentanediol; and polyols such as glycerin.

Of these, for the alcohol, propylene glycol, ethylene glycol, diethylene glycol, dipropylene glycol, 1-propanol, isopropanol, 1-butanol, 1-pentanol, 1-hexanol, 1-heptanol, 1-octanol, lauryl alcohol, 1-octadecanol, 2-ethylhexanol, or 2-octanol is preferred.

The solvents may be used singly or in combination of two or more thereof. When two or more solvents are used in combination, it is preferable that those solvents are miscible with each other.

The content of the solvent is preferably not less than 90 mass %, more preferably not less than 95 mass %, and even more preferably not less than 97 mass % with respect to the total mass of the chemical solution. The upper limit thereof is less than 100 mass %, preferably not more than 99.9 mass %, and more preferably not more than 99.7 mass %.

The content of the alcohol is preferably not more than 30 mass %, more preferably not more than 1 mass %, even more preferably not more than 200 mass ppm, and particularly preferably not more than 100 mass ppm with respect to the total mass of the chemical solution. The lower limit thereof is not particularly limited and is preferably not less than 5 mass ppm, more preferably not less than 10 mass ppm, and even more preferably not less than 30 mass ppm.

The alcohol content can be measured by, for instance, gas chromatography mass spectrometry (GC-MS).

### <Water>

The chemical solution may contain water.

Water is not particularly limited. Examples of the water include distilled water, ion exchanged water, pure water, and ultrapure water, with ultrapure water being preferred.

The content of the water is preferably less than 300 mass ppm, more preferably less than 200 mass ppm, even more preferably less than 100 mass ppm, particularly preferably less than 30 mass ppm, and most preferably less than 10 mass ppm with respect to the total mass of the chemical solution because the effects of the present invention are more excellent. The lower limit thereof is not particularly limited and is preferably not less than 1 mass ppm, and more preferably not less than 5 mass ppm.

The water may be any of water intentionally added, water inevitably contained in a raw material of the chemical solution, and water inevitably incorporated during manufacture, storage, and/or transportation of the chemical solution.

A method of adjusting the water content is not particularly limited, and examples thereof include a method that adds water, a method that removes water from the chemical solution and/or a raw material used for preparation of the chemical solution, and a combination thereof.

As a water removing method, known dehydrating methods can be used. Exemplary dehydrating methods include distillation, dehydration using a water adsorbent, and dehydration using a dehydration membrane.

The water content can be measured with a device that uses the Karl Fischer water content measurement technique as its measurement principle. As such an apparatus, “CA-200” (manufactured by Mitsubishi Chemical Aanalytech Co., Ltd.), “MKC-710M” (manufactured by Kyoto Electronics Manufacturing Co., Ltd.), and the like can be used, for example.

### <Other Components>

The chemical solution may contain other components than the foregoing components. Examples of such other components include acidic compounds and basic compounds.

The acidic compound is a compound showing an acidic property (pH of less than 7.0) in an aqueous solution, and examples thereof include inorganic acids such as hydrochloric acid, nitric acid, sulfuric acid, phosphoric acid, hydrobromic acid, and hydrofluoric acid, and organic acids such as p-toluenesulfonic acid, benzenesulfonic acid, methanesulfonic acid, and trifluoromethanesulfonic acid.

The basic compound is a compound showing a basic property (pH of more than 7.0) in an aqueous solution, and examples thereof include inorganic bases such as lithium hydroxide, sodium hydroxide, potassium hydroxide, cesium hydroxide, calcium hydroxide, strontium hydroxide, and barium hydroxide, and organic bases such as pyridine, and quaternary ammonium salt.

The acidic compounds and the basic compounds may be used singly or in combination of two or more thereof.

### <<Method of Manufacturing the Chemical Solution>>

### <Preparation Step>

The method of manufacturing the chemical solution is not particularly limited, and the chemical solution can be manufactured by mixing the foregoing components. The order or timing of mixing the components and the order and timing thereof are not particularly limited. One example of the method is, for example, a method in which the silicon-containing organic compound is added into a stirrer such as a mixer having a purified solvent therein and then sufficiently stirred, thus manufacturing the chemical solution.

The method of manufacturing the chemical solution may have a step selected from the group consisting of a distillation step in which a raw material is distilled, a dehydration step in which the chemical solution is dehydrated, a metal removal step in which a metal component is removed from the chemical solution, a filtration step in which the chemical solution is filtered, and a static elimination step in which static electricity is eliminated from the chemical solution.

### Container

For a container storing the chemical solution, known containers can be used.

A favorable container is one intended for semiconductor use, having high cleanliness in its inside, and allowing less leaching of impurities.

Examples of the container include the “Clean Bottle” series (manufactured by Aicello Corporation) and “Pure Bottle” (manufactured by Kodama Plastics Co., Ltd.). For the purpose of preventing impurities from being incorporated into a raw material and the chemical solution (i.e., preventing contamination), it is preferable to use a multilayer container having a six-layer structure in which the container's wall is composed of six resins or a seven-layer structure in which the container's wall is composed of seven resins.

For such a multilayer container, for example, containers described in JP 2015-123351 A can be adopted, and the contents thereof are incorporated in the present specification.

Exemplary materials of the inner wall of the container include at least one first resin selected from the group consisting of polyethylene resin, polypropylene resin, and polyethylene-polypropylene resin, a second resin different from the first resin, and metal such as stainless steel, Hastelloy, Inconel, or Monel. The inner wall of the container is preferably formed of or covered with any of the foregoing materials.

For the second resin, fluororesin (perfluororesin) is preferred. Use of fluororesin is preferred because this can minimize leaching of oligomers of ethylene or propylene.

Examples of the container include FluoroPure PFA composite drums (manufactured by Entegris, Inc.), and containers described in page 4 of JP H3-502677 A, page 3 of the pamphlet of WO 2004/016526, and pages 9 and 16 of the pamphlet of WO 99/046309.

For the inner wall of the container, in addition to fluororesin, other materials such as quartz and an electrolytically polished metal material are also preferred.

For the stainless steel, known stainless steels may be adopted for example.

In particular, stainless steel containing not less than 8 mass % of nickel is preferred, and austenitic stainless steel containing not less than 8 mass % of nickel is more preferred.

Examples of the metal include a Ni—Cr alloy. For the Ni—Cr alloy, known Ni—Cr alloys are usable.

In particular, a Ni—Cr alloy with a nickel content of 40 to 75 mass % and a chromium content of 1 to 25 mass % is preferred. The Ni—Cr alloy may optionally contain boron, silicon, tungsten, molybdenum, copper, or cobalt in addition to the foregoing alloy.

For the method of electrolytically polishing a metal material, known methods may be adopted for example. Specifically, the methods described in paragraphs [0011] to [0014] of JP 2015-227501 A and paragraphs [0036] to [0042] of JP 2008-264929 A can be adopted, and the contents thereof are incorporated in the present specification.

The metal material is preferably subjected to buffing. For a buffing method, known methods may be adopted for example.

The size of abrasive grains used in buffing finishing is preferably #400 or a smaller size because the asperities at a surface of the metal material can be reduced more easily. Buffing is preferably carried out before electrolytic polishing.

The metal material may be subjected to one or a combination of two or more of buffing, pickling, and magnetorheological finishing, the buffing including plural stages carried out with varying grit numbers, e.g., varying sizes of abrasive grains.

Preferably, the inside of the container is cleaned before being filled with the chemical solution.

A liquid used for cleaning can be selected as desired depending on the intended use, and a liquid containing the chemical solution or at least one of components blended in the chemical solution is preferred.

In order to prevent components in the chemical solution from changing during storage, the inside of the container may be replaced with an inert gas (e.g., nitrogen and argon) having a purity of not less than 99.99995 vol %. In particular, a gas with a low moisture content is preferred. Transportation and storage of the container storing the chemical solution therein may be carried out at normal temperature or controlled temperature. In particular, the temperature is preferably controlled within the range of −20° C. to 20° C. to prevent a change in quality.

### <<Specific Substrate>>

As described above, the specific substrate is a substrate having on its surface at least two regions of a first region containing silicon and a second region made from a material different from that of the first region.

The first region preferably has a functional group on its surface. The functional group is preferably a functional group which reacts upon contact with the silicon-containing organic compound whereby a silicon atom-containing group (e.g., silyl group) is introduced to the functional group, and examples thereof include a hydroxyl group, an amino group, a carboxy group, and an amido group, with a hydroxyl group being preferred.

The first region is not particularly limited as long as it contains silicon, and is preferably a region containing at least one material selected from the group consisting of silicon, silicon oxide, silicon nitride, silicon carbide, silicon carbonitride, silicon oxycarbide, silicon oxycarbon nitride, and silicon germanium (hereinafter also called “silicon compound group”), and more preferably a region constituted of at least one material selected from the silicon compound group. In particular, the first region preferably contains silicon oxide, and is more preferably a region constituted of silicon oxide.

Specific examples of the silicon oxide include a material represented by the composition of SiO_{y} (where y is preferably 0.5 to 2.0 and more preferably 1.0 to 2.0), and specific examples of the silicon oxycarbide include a material represented by the composition of SiO_{z}C_{w} (where z is preferably 0.5 to 2.0 and more preferably 1.0 to 2.0, and w is preferably 0.5 to 2.0 and more preferably 1.0 to 2.0).

The material represented by the composition of SiO_{y} and the material represented by the composition of SiO_{z}C_{w} may further contain hydrogen. Exemplary materials represented by the composition of SiO_{z}C_{w} include Si(OC₂H₅)₄ (tetraethyl orthosilicate, TEOS).

The first region may contain other materials than silicon. Examples of other materials than silicon include metal. The metal may be a simple substance or an alloy. Examples of the metal include a metal containing aluminum (Al), tantalum (Ta), zirconium (Zr), or lanthanum (La).

The first region is often a region constituted of an insulator.

A method of forming the first region is not particularly limited and known methods may be used; examples of the method include chemical vapor deposition (CVD), physical vapor deposition, plasma irradiation, heat treatment of a silicon substrate, and application of a precursor compound.

The second region is not particularly limited as long as it is a region made from a material different from that of the first region, and one example thereof is a region made from a metal material.

The type of the metal is not particularly limited, and the metal is for example at least one selected from the group consisting of aluminum (Al), copper (Cu), ruthenium (Ru), cobalt (Co), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), and iridium (Ir).

The metal material may be a simple substance or an alloy. The metal material may be metal oxide, metal nitride, or metal oxynitride that contains an element other than the foregoing metals. Exemplary elements other than the metals include oxygen, hydrogen, phosphorus, and nitrogen.

The second region may be a region containing silicon as long as it is constituted of a material different from a material of the first region. When the second region contains silicon, the second region may be for example a region containing silicon nitride, and is preferably a region constituted of silicon nitride.

It is also preferable that the second region not have the foregoing functional group on its surface.

The specific substrate may have a third region made from a material different from that of the first region and that of the second region.

A method of forming the second region is not particularly limited, and known methods may be used. Examples of the method include plating and physical vapor deposition, as exemplified by CVD, plasma irradiation, heat treatment of a silicon substrate, and application of a precursor compound.

Exemplary combinations of the first region and the second region include those combinations shown in Examples 1 to 3 as follows.
(Example 1) First region: a region constituted of silicon oxide; second region: a region constituted of silicon nitride
(Example 2) First region: a region constituted of silicon nitride; second region: a region constituted of aluminum oxide
(Example 3) First region: a region constituted of silicon oxide; second region: a region constituted of silicon nitride; third region: a region constituted of aluminum oxide

Next, specific procedures of the step 1 (a step of bringing the specific substrate and the chemical solution into contact) are described in detail. By carrying out the step 1, a coating (preferably, a silicon atom-containing coating) derived from the silicon-containing organic compound can be formed on the first region. Owing to the coating, etching carried out in the step 3 can be inhibited.

The contact angle of water in the first region after the step 1 is preferably not less than 70°, more preferably not less than 80°, and even more preferably not less than 90° because the effects of the invention are more excellent. The upper limit thereof is not particularly limited and is usually not more than 1200.

The contact angle of water is determined by the following method.

A value of contact angle 500 milliseconds after a water drop makes contact with a surface of a measurement object is measured three times by means of a contact angle meter (DMs-501, manufactured by Kyowa Interface Science Co., Ltd.), and the average thereof is defined as the contact angle.

A method of contacting above is not particularly limited, and known methods may be used. Examples thereof include a method in which the chemical solution is applied or sprayed onto the specific substrate, and a method in which the specific substrate is immersed in the chemical solution. The chemical solution may be circulated when the specific substrate is immersed in the chemical solution.

The temperature of the chemical solution at contacting is not particularly limited and is preferably 10° C. to 50° C.

The time of contact between the chemical solution and the specific substrate is not particularly limited and is preferably 10 seconds to 10 hours, more preferably 30 seconds to 1 hour, and even more preferably 1 minute to 30 minutes.

The specific substrate may be pretreated before the step 1. Exemplary pretreatments include surface activation treatment and cleaning treatment.

Examples of the surface activation treatment include treatment of contacting with a pretreatment solution, plasma treatment, corona treatment, and ozone treatment.

For a method of contacting with the pretreatment solution, the same methods as the methods of bringing the specific substrate and the chemical solution into contact may be used, and the method in which the specific substrate is immersed in the chemical solution is preferred. The pretreatment solution may be circulated during the immersion.

Examples of the pretreatment solution include an aqueous solution containing an acidic compound. Examples of the acidic compound include hydrogen fluoride, hexafluorosilicate, hexafluorotitanate, hexafluorozirconate, hexafluorophosphate, tetrafluoroborate, and salts thereof, with hydrogen fluoride being preferred. The content of the acidic compound is preferably 0.01 to 5 mass %, more preferably 0.1 to 2 mass %, and even more preferably 0.1 to 5 mass % with respect to the total mass of the pretreatment solution.

The temperature of the pretreatment solution at contacting is not particularly limited and is preferably 10° C. to 60° C.

The time of contact between the pretreatment solution and the specific substrate is not particularly limited and is preferably 10 seconds to 10 hours, more preferably 10 seconds to 1 hour, and even more preferably 30 seconds to 30 minutes.

The methods of the plasma treatment and the ozone treatment are not particularly limited, and known methods may be used.

Examples of the cleaning treatment include a method in which a cleaning solution such as water or an organic solvent is brought into contact with the specific substrate. For a method of bringing the cleaning solution and the specific substrate into contact, the same methods as the methods of bringing the pretreatment solution and the specific substrate into contact may be used.

### (Step 2)

Next, the step 2 is detailed.

The step 2 is a step of bringing the substrate having undergone the step 1 and an organic solvent into contact (hereinafter also referred to as “rinsing treatment”).

The silicon-containing organic compound remaining on the second region can be removed by the step 2, and this leads to excellent etch selectivity between the first region and the second region.

A contacting method is not particularly limited and may be the same as the methods in the step 1. The temperature at contacting is not particularly limited and is preferably 10° C. to 50° C.

For the organic solvent, known organic solvents may be used, and examples thereof include those listed in the description of the solvent described with respect to the step 1 above. For the organic solvent, the alcohol and the non-protic solvent described above are applicable for instance, with the alcohol being preferred.

Preferred embodiments of the alcohol are the same as those described with respect to the step 1.

### (Step 3)

Finally, the step 3 is detailed.

The step 3 is a step of bringing the substrate having undergone the step 2 and a treatment solution containing at least one of hydrogen fluoride, potassium hydroxide, ammonia, tetramethylammonium hydroxide, or hydrogen peroxide into contact, to thereby etch the second region.

The treatment solution is preferably an aqueous solution containing at least one of hydrogen fluoride, potassium hydroxide, ammonia, tetramethylammonium hydroxide, or hydrogen peroxide (which are hereinafter also collectively referred to as “etching compound”), preferably an aqueous hydrogen fluoride solution, an aqueous potassium hydroxide solution, an aqueous ammonia solution, an aqueous tetramethylammonium hydroxide solution, or an aqueous hydrogen peroxide solution, more preferably an aqueous hydrogen fluoride solution, an aqueous potassium hydroxide solution, or an aqueous ammonia solution, and even more preferably an aqueous hydrogen fluoride solution.

The concentration of an aqueous solution of the etching compound above is not particularly limited and is usually 0.1 to 50 mass %.

A method of bringing the substrate having undergone the step 2 and the foregoing treatment solution into contact may be the same as the methods in the step 1. The temperature at contacting is not particularly limited and is preferably 10° C. to 50° C.

### (Step 4)

The method of manufacturing a treated substrate according to the present invention may have a step of heating the substrate (hereinafter also referred to as “step 4”); however, it is preferable to not have a step of heating the substrate at least one of between the step 1 and the step 2 or between the step 2 and the step 3.

When the step 4 is carried out, the heating temperature is not particularly limited and is preferably 50° C. to 300° C. and more preferably 60° C. to 180° C. A heating method is not particularly limited, and examples thereof include a method that brings the substrate into contact with a heating element (e.g., heating using a hot plate) and a method that irradiates the substrate with infrared light.

### (ALD Step (Step 5))

In the method of manufacturing a treated substrate according to the present invention, the step 3 may optionally be followed by atomic layer deposition (ALD). The coating formed in the step 1 can also function as a mask in deposition of a material on the substrate by ALD.

A method of ALD is not particularly limited, and known methods may be used.

One exemplary method is a method in which gas of a precursor that serves as a starting material of a film (ALD film) to be formed by depositing a material by ALD is supplied to a surface of a substrate, and subsequently, the starting material is decomposed and/or chemically reacted by use of an oxidizer or the like to deposit a material, thereby forming an ALD film.

The precursor is not particularly limited, known precursors may be used depending on the type of an ALD film to be formed, and examples thereof include an organic metal compound. For the precursor, use may be made of compounds described in paragraphs [0021] to [0025] of JP 2022-080800 A.

The oxidizer is not particularly limited, known oxidizers for use in ALD may be adopted, and examples thereof include water, oxygen, and ozone.

A material constituting the ALD film can be controlled by, for instance, the type of the precursor applied, the atmosphere of supply, and the oxidizer.

The material of the ALD film formed is not particularly limited, and examples thereof include a metal, a metal oxide, and a metal nitride. Examples of the metal include aluminum, titanium, chromium, iron, cobalt, nickel, copper, zinc, yttrium, zirconium, niobium, molybdenum, ruthenium, palladium, lanthanum, cerium, hafnium, tantalum, tungsten, platinum, and bismuth.

Examples of the metal oxide include aluminum oxide, titanium oxide, zinc oxide, zirconium oxide, hafnium oxide, and tantalum oxide. Examples of the metal nitride include titanium nitride and tantalum nitride.

### {Method of Manufacturing a Semiconductor}

The method of manufacturing a treated substrate can be favorably applied to a method of manufacturing a semiconductor, and the present invention also includes the method of manufacturing a semiconductor.

### EXAMPLES

The present invention is described below in further detail based on examples.

The materials, amounts of use, ratios, treatments and treatment procedures illustrated in the examples below may be modified as appropriate as long as they do not depart from the scope and spirit of the present invention. Therefore, the scope of the present invention should not be construed as being limited to the following examples.

Preparation, filling, storage, and the like of chemical solutions were all conducted in a cleanroom with the level satisfying ISO Class 2 or lower class. Containers for use were used after being cleaned with a solvent used in preparation or a prepared chemical solution.

### {Preparation of a Chemical Solution}

Relevant components (silicon-containing organic compound, alcohol, and water) were added to a non-protic polar solvent such that their contents were as shown in Table 1 below, thereby preparing each of chemical solutions used in Examples and Comparative Examples. Components used in preparation of chemical solutions are shown below.

It should be noted that non-protic polar solvents used were those of super dehydrated grade.

### (Silicon-Containing Organic Compound)

HMDS (hexamethyldisilazane)
TMDS (tetramethyldisilazane)
Butyldimethyl(dimethylamino)silane
Octadecyltrimethoxysilane
Phenethyldimethyl(dimethylamino)silane

### (Non-Protic Polar Solvent)

Propylene carbonate
γ-Butyrolactone

### (Alcohol)

IPA (2-propanol)

The content of water (water content) in a chemical solution was determined with a Karl Fischer device (trace moisture meter, CA-200, manufactured by Mitsubishi Chemical Aanalytech Co., Ltd.). Specifically, the amount of water vaporized from a sample was measured by a coulometric titration-thermal evaporation method (vial method) using Aquamicron AX as an anolyte and Aquamicron CXU as a catholyte. The heating temperature was 140° C.

### {Preparation of a Treated Substrate}

A silicon oxide substrate, a silicon nitride substrate, and an aluminum oxide substrate were subjected to the step 1, the step 2, the step 3, and optionally the step 4 shown in Table 2 below in accordance with the procedures described below, thereby preparing each of treated substrates of Examples and Comparative Examples.

### <Step 1 (Chemical Solution Treatment Step)>

A coating was formed on a substrate using each of chemical solutions of Examples and Comparative Examples in accordance with the following procedures.

For the substrate, a silicon oxide substrate, a silicon nitride substrate, and an aluminum oxide substrate were prepared as follows.

The silicon oxide substrate and the silicon nitride substrate were respectively prepared by forming a silicon oxide layer and a silicon nitride layer, each of which was formed on one surface of a commercially available silicon wafer (diameter: 12 inches) by CVD. The treatment time of CVD was adjusted to have a film thickness of the silicon oxide layer of 100 nm and a film thickness of the silicon nitride layer of 30 nm.

The aluminum oxide substrate was prepared by forming an aluminum oxide layer on one surface of a commercially available silicon wafer (diameter: 12 inches) by ALD. Trimethyl aluminum was used as an organic metal starting material, water was used as an oxidizer, and the ALD treatment temperature was 150° C. The number of ALD cycles was adjusted to have a film thickness of the aluminum oxide layer of 30 nm.

Subsequently, each of the obtained substrates was cut into 2 cm square. Each of the cut silicon oxide substrate and the cut silicon nitride substrate was immersed into 0.1 mass % aqueous hydrogen fluoride solution, and the cut aluminum oxide substrate was immersed into 0.02 mass % aqueous hydrogen fluoride solution, thus carrying out pretreatment. The pretreatment was carried out while stirring the aqueous solution at a stirring speed of 250 rpm, the temperature of the aqueous solution was 25° C., and the immersion time was 1 minute. The pretreated substrates were sprayed with nitrogen gas and thereby dried.

Subsequently, the pretreated wafers were each immersed into a relevant chemical solution to form a coating (silicon atom-containing coating). The coating formation was carried out while stirring the chemical solution at a stirring speed of 250 rpm, the temperature of the chemical solution was 25° C., and the immersion time was 10 minutes.

### <Step 2 (Cleaning Step)>

Next, each of the substrates having undergone the step 1 was immersed in IPA, thereby carrying out cleaning treatment (rinsing treatment).

The rinsing treatment was carried out while stirring IPA at a stirring speed of 250 rpm, the temperature of IPA was 25° C., and the rinsing time was 30 seconds. The rinsed substrates were sprayed with nitrogen gas and thereby dried.

Modified substrates each having a silicon atom-containing coating thereon were obtained by the foregoing procedures.

### <Step 3 (Etching Step)>

Each of the modified substrates obtained in the step 2 was immersed in a relevant treatment solution stated in Table 1 below, thereby carrying out etching treatment.

For the treatment solution, an aqueous hydrogen fluoride solution (0.4 mass %) or an aqueous potassium hydroxide solution (30 mass %) was used.

The etching treatment was carried out while stirring the treatment solution at a stirring speed of 250 rpm. As for the temperature of the treatment solution, the aqueous hydrogen fluoride solution was at 25° C., and the aqueous potassium hydroxide solution was at 80° C. As for the etch time, each modified substrate was etched under four conditions of 30 seconds, 1 minute, 3 minutes, and 10 minutes.

Finally, the substrates having undergone the treatment were sprayed with nitrogen gas and thereby dried. Thus, treated substrates were obtained.

### <Step 4 (Heating Step)>

As shown in Table 2, heat treatment was carried out, prior to the step 2, on the modified substrates obtained in the step 1 in Example 3 and, prior to the step 3, on the modified substrates obtained in the step 2 in Example 4. Each substrate was heated using a hot plate at 120° C. for 5 minutes in a nitrogen atmosphere.

### {Evaluation}

### <Contact Angle Evaluation>

The contact angle of water with each of the modified substrates was measured by the following method.

A value of contact angle 500 milliseconds after a water drop made contact with a surface was measured three times by means of a contact angle meter (DMs-501, manufactured by Kyowa Interface Science Co., Ltd.), and the average thereof was defined as the contact angle (°). The analysis was made assuming the surface tension of water being 72.9 mN/m, and the measurement was carried out in an environment of 23° C.

### <Etch Rate (ER) Evaluation>

The etch rate (ER) [nm/sec] of each of the modified substrates in the step 3 was measured by the following method.

For the silicon oxide layer, the silicon nitride layer, or the aluminum oxide layer formed on a surface of each of the modified substrates, the film thickness (nm) of the layer before the step 3 and the film thickness (nm) of the layer after the step 3 were measured with a spectroscopic ellipsometer (M-2000XI, manufactured by J.A. Woollam Japan).

The measurement was carried out at three points in each sample, and the average thereof was defined as the film thickness (nm). The measurement conditions were the measurement range being 1.2 to 2.5 eV and the measurement angle being 70° and 750.

As for the etch time, each substrate was etched under four conditions of 30 seconds, 1 minute, 3 minutes, and 10 minutes. The etch rate was calculated from the relation between the etch time and the change in film thickness (the film thickness (nm) before the step 3—the film thickness (nm) after the step 3). It should be noted that the etch rate was calculated using data of a time region during which the film thickness changes linearly with respect to the etch time.

As the change in film thickness increases, the ER increases, which means that the relevant layer is more easily etched in the step 3.

### {Results}

Table 1 shows compositions of chemical solutions, and Table 2 shows Done or Not done of the steps 1 to 4 and evaluation results of Examples and Comparative Examples.

In Table 1, “mass %” represents the mass % concentration with respect to the total mass of the chemical solution, and “ppm” represents the mass ppm concentration with respect to the total mass of the chemical solution.

In Table 1, the water content is a measurement determined by the above-described method.

In Table 1, the balance obtained after excluding the silicon-containing organic compound, the alcohol, and water from the chemical solution is the non-protic polar solvent.

In Table 1, components stated with “/” therebetween are those mixed at a specified ratio. For instance, “Propylene carbonate/γ-butyrolactone=1/1” means that a mixed solvent of propylene carbonate and γ-butyrolactone was used at a mass ratio of propylene carbonate/γ-butyrolactone=1/1 as the non-protic polar solvent.

In Table 2, “Done” means that a step stated in the same column was carried out, while “Not done” means that the step was not carried out. The column of “Type of treatment solution used in etching step” shows solutes in aqueous solutions used as treatment solutions. For instance, it can be seen that in the case of Example 3, the step 1 was followed by the step 4, thereafter the step 2 was carried out without being followed by the step 4, and finally, the step 3 was carried out using the aqueous hydrogen fluoride solution as the treatment solution.

TABLE 1

| | Composition of chemical solution | | | | |
|---|---|---|---|---|---|
| | Silicon-containing organic compound | | Solvent | | Water |
| | | Content | | Content | content |
| | Type | (mass %) | Type | (mass %) | (ppm) |
| EX 1 | HMDS | 1 | Propylene carbonate | Balance | 5 |
| EX 2 | HMDS | 1 | Propylene carbonate | Balance | 5 |
| EX 3 | HMDS | 1 | Propylene carbonate | Balance | 12 |
| EX 4 | HMDS | 1 | Propylene carbonate | Balance | 10 |
| EX 5 | HMDS | 1 | γ-Butyrolactone | Balance | 11 |
| EX 6 | HMDS | 1 | Propylene carbonate/ | Balance | 5 |
| | | | γ-butyrolactone = 1/1 | | |
| EX 7 | HMDS | 1 | Propylene carbonate/IPA = 9/1 | Balance | 5 |
| EX 8 | HMDS | 1 | Propylene carbonate/IPA = 8/2 | Balance | 5 |
| EX 9 | HMDS | 1 | Propylene carbonate/IPA = 7/3 | Balance | 5 |
| EX 10 | HMDS | 1 | Propylene carbonate | Balance | 42 |
| EX 11 | HMDS | 1 | Propylene carbonate | Balance | 85 |
| EX 12 | HMDS | 1 | Propylene carbonate | Balance | 120 |
| EX 13 | TMDS | 1 | Propylene carbonate | Balance | 8 |
| EX 14 | Butyldimethyl(dimethylamino) | 1 | Propylene carbonate | Balance | 7 |
| | silane | | | | |
| EX 15 | Phenethyldimethyl(dimethylamino) | 1 | Propylene carbonate | Balance | 7 |
| | silane | | | | |
| EX 16 | Octadecyltrimethoxysilane | 1 | Propylene carbonate | Balance | 5 |
| CE 1 | — | — | — | — | — |
| CE 2 | — | — | — | — | — |
| CE 3 | HMDS | 1 | Propylene carbonate | Balance | 8 |

EX: Example
CE: Comparative Example

TABLE 2

| | Preparation of processed substrate | | | | | Evaluation results | | | | | |
|---|---|---|---|---|---|---|---|---|---|---|---|
| | | Heating | | Heating | Type of | Silicon oxide | | Silicon nitride | | Aluminum oxide | |
| | Chemical | step | | step | treatment | substrate | | substrate | | substrate | |
| | solution | (before | | (after | solution | Contact | | Contact | | Contact | |
| | treatment | cleaning | Cleaning | cleaning | used in | angle | ER | angle | ER | angle | ER |
| | step | step) | step | step) | etching step | (°) | [nm/min] | (°) | [nm/min] | (°) | [nm/min] |
| EX 1 | Done | Not done | Done | Not done | Hydrogen | 98 | 0.3 | 78 | 2.4 | 32 | 9 |
| | | | | | fluoride | | | | | | |
| EX 2 | Done | Not done | Done | Not done | Potassium | 98 | 0.1 | 78 | 1.4 | 32 | 850 |
| | | | | | hydroxide | | | | | | |
| EX 3 | Done | Done | Done | Not done | Hydrogen | 97 | 0.3 | 82 | 2 | 45 | 7.6 |
| | | | | | fluoride | | | | | | |
| EX 4 | Done | Not done | Done | Done | Hydrogen | 98 | 0.3 | 80 | 2.2 | 38 | 8.2 |
| | | | | | fluoride | | | | | | |
| EX 5 | Done | Not done | Done | Not done | Hydrogen | 98 | 0.3 | 78 | 2.4 | 30 | 9 |
| | | | | | fluoride | | | | | | |
| EX 6 | Done | Not done | Done | Not done | Hydrogen | 97 | 0.3 | 78 | 2.4 | 30 | 9 |
| | | | | | fluoride | | | | | | |
| EX 7 | Done | Not done | Done | Not done | Hydrogen | 92 | 0.5 | 72 | 2.6 | 30 | 9 |
| | | | | | fluoride | | | | | | |
| EX 8 | Done | Not done | Done | Not done | Hydrogen | 84 | 0.6 | 65 | 2.8 | 29 | 9 |
| | | | | | fluoride | | | | | | |
| EX 9 | Done | Not done | Done | Not done | Hydrogen | 65 | 0.9 | 59 | 2.9 | 28 | 9 |
| | | | | | fluoride | | | | | | |
| EX 10 | Done | Not done | Done | Not done | Hydrogen | 96 | 0.4 | 76 | 2.5 | 30 | 9 |
| | | | | | fluoride | | | | | | |
| EX 11 | Done | Not done | Done | Not done | Hydrogen | 93 | 0.4 | 73 | 2.6 | 31 | 9 |
| | | | | | fluoride | | | | | | |
| EX 12 | Done | Not done | Done | Not done | Hydrogen | 84 | 0.6 | 66 | 2.8 | 32 | 8.9 |
| | | | | | fluoride | | | | | | |
| EX 13 | Done | Not done | Done | Not done | Hydrogen | 103 | 0.2 | 82 | 2 | 30 | 9 |
| | | | | | fluoride | | | | | | |
| EX 14 | Done | Not done | Done | Not done | Hydrogen | 86 | 0.7 | 68 | 2.7 | 32 | 8.9 |
| | | | | | fluoride | | | | | | |
| EX 15 | Done | Not done | Done | Not done | Hydrogen | 72 | 0.9 | 61 | 2.9 | 30 | 9 |
| | | | | | fluoride | | | | | | |
| EX 16 | Done | Not done | Done | Not done | Hydrogen | 68 | 0.9 | 59 | 2.9 | 33 | 8.9 |
| | | | | | fluoride | | | | | | |
| CE 1 | Not done | Not done | Not done | Not done | Hydrogen | 5 | 4.3 | 30 | 24 | 30 | 9 |
| | | | | | fluoride | | | | | | |
| CE 2 | Not done | Not done | Not done | Not done | Potassium | 5 | 9.2 | 28 | 6.8 | 30 | 850 |
| | | | | | hydroxide | | | | | | |
| CE 3 | Done | Not done | Not done | Not done | Hydrogen | 95 | 0.3 | 92 | 0.9 | 68 | 0.9 |
| | | | | | fluoride | | | | | | |

EX: Example
CE: Comparative Example

The results in the tables reveal that the method of manufacturing a treated substrate according to the present invention can, in a substrate having on its surface at least two regions of a first region containing silicon and a second region made from a material different from that of the first region, suppress etching of the first region and achieve high etch selectivity between the two regions.

For example, comparison between the silicon oxide substrate and the aluminum oxide substrate in Example 1 demonstrates that etching of the silicon oxide substrate is suppressed and the etch selectivity between the silicon oxide substrate and the aluminum oxide substrate is high, while that effect is not obtained in Comparative Examples 1 and 3.

The same can be said from comparison between the silicon nitride substrate and the aluminum oxide substrate and comparison between the silicon oxide substrate and the silicon nitride substrate.

When a substrate A having two layers of the silicon oxide layer (first region) and the aluminum oxide layer (second region), a substrate B having two layers of the silicon nitride layer (first region) and the aluminum oxide layer (second region), and a substrate C having two layers of the silicon oxide layer (first region) and the silicon nitride layer (second region) were each subjected to the steps 1 to 3 (and optionally the step 4), a similar tendency to that shown in the above tables was demonstrated.

Comparison among Examples 1 to 5 and the like reveals that when a step of heating a substrate (step 4) is not carried out at least between the step 1 and the step 2 or between the step 2 and the step 3, the etch selectivity is still higher.

Comparison among Examples 1 and 5 to 9 and the like reveals that when a solvent in a chemical solution contains a non-protic polar solvent and the content of the non-protic polar solvent is not less than 80 mass % with respect to the total mass of the solvent contained in the chemical solution, etching of the first region is more suppressed, and the etch selectivity is still higher.

Comparison among Examples 1 and 10 to 12 and the like reveals that when the water content is less than 100 ppm with respect to the total mass of a chemical solution, etching of the first region is more suppressed, and the etch selectivity is still higher.

Comparison among Example 1 and 13 to 16 and the like reveals that when a silicon-containing organic compound is an organic silazane compound, etching of the first region is more suppressed, and the etch selectivity is still higher.

What is claimed is:

1. A method of manufacturing a treated substrate, the method comprising:
a step 1 of bringing a substrate and a chemical solution into contact, the substrate having on its surface at least two regions of a first region containing silicon and a second region made from a material different from that of the first region, the chemical solution containing a silicon-containing organic compound and a solvent;
a step 2 of bringing the substrate having undergone the step 1 and an organic solvent into contact; and
a step 3 of bringing the substrate having undergone the step 2 and a treatment solution containing at least one of hydrogen fluoride, potassium hydroxide, ammonia, tetramethylammonium hydroxide, or hydrogen peroxide into contact, to thereby etch the second region.

2. The method of manufacturing a treated substrate according to claim 1,
wherein a step of heating the substrate is not carried out at least between the step 1 and the step 2 or between the step 2 and the step 3.

3. The method of manufacturing a treated substrate according to claim 1,
wherein the solvent in the chemical solution contains a non-protic polar solvent, and a content of the non-protic polar solvent is not less than 80 mass % with respect to a total mass of the solvent.

4. The method of manufacturing a treated substrate according to claim 1,
wherein a content of water is less than 100 mass ppm with respect to a total mass of the chemical solution.

5. The method of manufacturing a treated substrate according to claim 1,
wherein the silicon-containing organic compound includes an organic compound having a Si—N bond.

6. The method of manufacturing a treated substrate according to claim 1,
wherein the silicon-containing organic compound is an organic silazane compound or a compound represented by Formula (1), 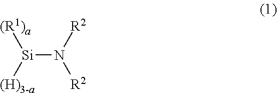
where R¹'s each independently represent a hydrocarbon group that may have a halogen atom, R²'s each independently represent a hydrogen atom, a hydrocarbon group that may have a halogen atom, or an acyl group that may have a halogen atom, and a represents an integer of 1 to 3.

7. The method of manufacturing a treated substrate according to claim 1,
wherein the silicon-containing organic compound is an organic silazane compound.

8. The method of manufacturing a treated substrate according to claim 1,
wherein a molecular weight of the silicon-containing organic compound is less than 200.

9. The method of manufacturing a treated substrate according to claim 1,
wherein the first region is a region containing at least one material selected from the group consisting of silicon, silicon oxide, silicon nitride, silicon carbide, silicon carbonitride, silicon oxycarbide, silicon oxycarbon nitride, and silicon germanium.

10. The method of manufacturing a treated substrate according to claim 1,
wherein the first region contains silicon oxide.

11. A method of manufacturing a semiconductor, the method comprising the method of manufacturing a treated substrate according to claim 1.

12. The method of manufacturing a treated substrate according to claim 2,
wherein the solvent in the chemical solution contains a non-protic polar solvent, and a content of the non-protic polar solvent is not less than 80 mass % with respect to a total mass of the solvent.

13. The method of manufacturing a treated substrate according to claim 2,
wherein a content of water is less than 100 mass ppm with respect to a total mass of the chemical solution.

14. The method of manufacturing a treated substrate according to claim 2,
wherein the silicon-containing organic compound includes an organic compound having a Si—N bond.

15. The method of manufacturing a treated substrate according to claim 2,
wherein the silicon-containing organic compound is an organic silazane compound or a compound represented by Formula (1), 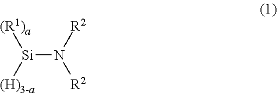
where R¹'s each independently represent a hydrocarbon group that may have a halogen atom, R²'s each independently represent a hydrogen atom, a hydrocarbon group that may have a halogen atom, or an acyl group that may have a halogen atom, and a represents an integer of 1 to 3.

16. The method of manufacturing a treated substrate according to claim 2,
wherein the silicon-containing organic compound is an organic silazane compound.

17. The method of manufacturing a treated substrate according to claim 2,
wherein a molecular weight of the silicon-containing organic compound is less than 200.

18. The method of manufacturing a treated substrate according to claim 2,
wherein the first region is a region containing at least one material selected from the group consisting of silicon, silicon oxide, silicon nitride, silicon carbide, silicon carbonitride, silicon oxycarbide, silicon oxycarbon nitride, and silicon germanium.

19. The method of manufacturing a treated substrate according to claim 2,
wherein the first region contains silicon oxide.

20. A method of manufacturing a semiconductor, the method comprising the method of manufacturing a treated substrate according to claim 2.
